(19) United States
(12) Patent Application Publication
(10) Pub. No.: US 2015/0129289 A1
(43) Pub. Date: May 14, 2015

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Gun Woo Kim, Suwon-Si (KR); Eung Suek Lee, Suwon-Si (KR); Yoong Oh, Suwon-Si (KR); Sung Uk Lee, Suwon-Si (KR)

(73) Assignee: SAMSUNG ELECTRO-MECHANICS CO., LTD., Suwon-Si (KR)

(21) Appl. No.: 14/536,384

(22) Filed: Nov. 7, 2014

(30) Foreign Application Priority Data
Nov. 8, 2013 (KR) 10-2013-0135498

(51) Int. Cl. H05K 1/09; H05K 1/11

(52) U.S. Cl. CPC H05K 1/092; H05K 1/11
USPC 174/255; 204/192.12; 204/192.11

(57) ABSTRACT

There are provided a printed circuit board and a method of manufacturing the same. The printed circuit board according to an exemplary embodiment of the present disclosure includes: a substrate; a metal root layer formed by injecting and depositing metal particles into and on the substrate; and a circuit layer formed on the metal root layer.

### CROSS-REFERENCE TO RELATED APPLICATION

This application claims the foreign priority benefit of Korean Patent Application No. 10-2013-0135498, filed on Nov. 8, 2013, entitled “Printed Circuit Board and Method of Manufacturing the Same” which is hereby incorporated by reference in its entirety into this application.

### BACKGROUND

Embodiments of the present disclosure relates to a printed circuit board and a method of manufacturing the same.

In accordance with a trend toward miniaturization and thinness of a printed circuit board, a line and a space of a metal pattern have been shirked and a thickness of a metal seed layer has also been thinned accordingly. In addition, after a thin film is implemented on various nonconductor substrates, adhesion between interfaces has been required. As an alternative, a technical trend has been changed from an existing method of forming a metal seed layer by chemical copper to a method of forming a metal seed layer by vacuum deposition. A technology of forming a metal seed layer by vacuum deposition generally has a layer structure having a buffer layer to attach a desired metal material onto a base material, which is the nonconductor. The buffer layer serves to hold both a substrate, which is the base material, and the metal layer to be deposited. In addition, as a unit which causes the buffer layer to well hold both layers, wet and dry processes of various pre-processing concepts have also been demanded.

### RELATED ART DOCUMENT

### Patent Document

(Patent Document 1) Japanese Patent Laid-Open Publication No. 2011-137230

### SUMMARY

An aspect of the present disclosure may provide a printed circuit board capable of forming a metal thin film by injecting metal particles into a substrate and then forming a coupling of the metal particles by a heat treatment. An aspect of the present disclosure may also provide a printed circuit board capable of reducing costs of production and time of production, and a method of manufacturing the same.

According to an aspect of the present disclosure, a printed circuit board may include: a substrate; a metal root layer formed by injecting and depositing metal particles into and on the substrate; and a circuit layer formed on the metal root layer.

The metal root layer may be formed on the entire surface of the substrate.

The metal root layer may be formed on a region of the substrate bonded to the circuit layer.

The metal root layer may have a discontinuous chain structure.

The metal root layer may be made of cooper, nickel, chrome, or an alloy thereof.

According to another aspect of the present disclosure, a method of manufacturing a printed circuit board may include: preparing a substrate; injecting metal particles into the substrate; depositing a metal root layer by applying heat to the metal particles; and forming a circuit layer on the metal root layer.

In the injecting of the metal particles, the metal particles may be injected by sputtering.

The method may further include, after the preparing of the substrate, removing foreign material from the substrate.

The method may further include, after the removing of the foreign material from the substrate, removing moisture from the substrate.

The method may further include, before the injecting of the metal particles, forming a mask having an opening; and after the injecting of the metal particles, removing the mask having the opening.

The metal root layer may be formed on a surface bonded to the circuit layer.

The metal root layer may be formed on the entire surface of the substrate.

The metal root layer may have a discontinuous chain structure.

The metal root layer may be made of cooper, nickel, chrome, or an alloy thereof.

### BRIEF DESCRIPTION OF DRAWINGS

The above and other aspects, features and other advantages of the present disclosure will be more clearly understood from the following detailed description taken in conjunction with the accompanying drawings, in which:

FIGS. 1 and 2 are cross-sectional views of a printed circuit board according to an exemplary embodiment of the present disclosure; and

FIGS. 3 to 12 are process flow charts of a method of manufacturing a printed circuit board according to another exemplary embodiment of the present disclosure.

### DETAILED DESCRIPTION

The aspects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

Printed Circuit Board

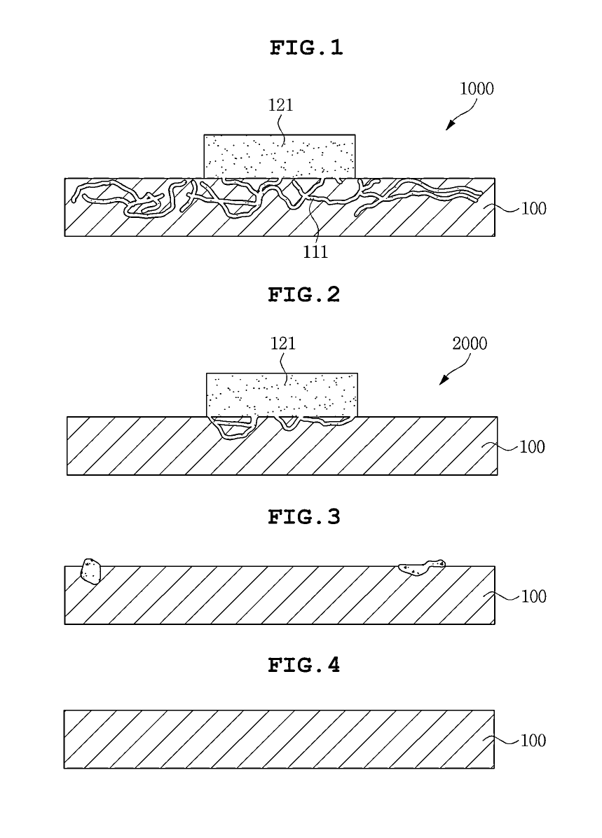

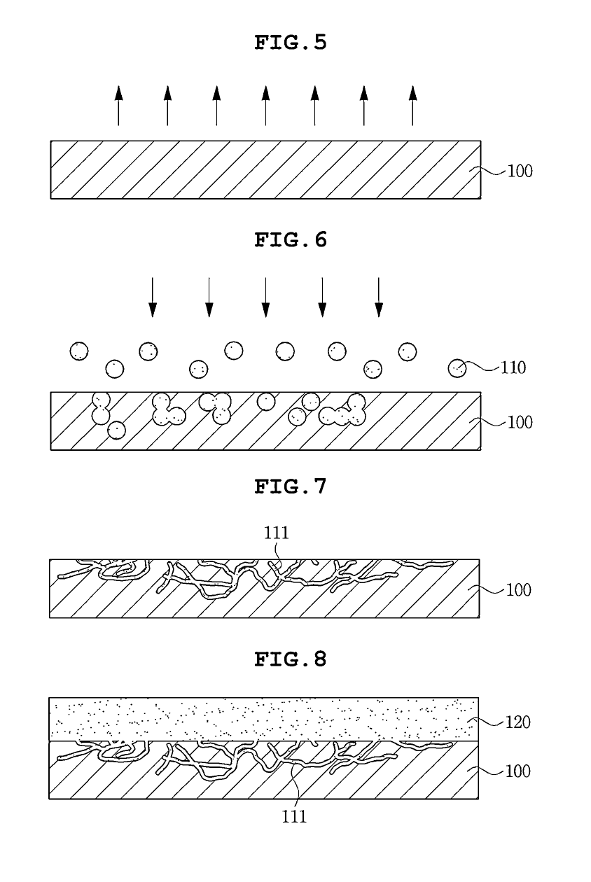

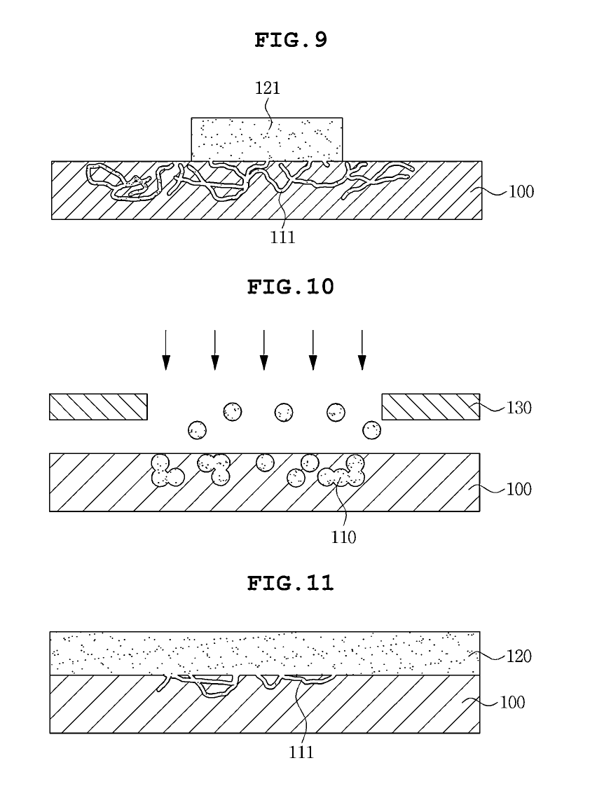

FIG. 1 is a cross-sectional view of a printed circuit board 1000 according to an exemplary embodiment of the present disclosure.

As shown in FIG. 1, the printed circuit board 1000 according to the exemplary embodiment of the present disclosure may include a substrate 100, a metal root layer 111 formed by injecting and depositing metal particles into and on the substrate 100, and a circuit layer 121 formed on the metal root layer 111.

The metal root layer 111 may be formed on the entire surface of the substrate 100 and may have a discontinuous chain structure.

The substrate 100, which is a circuit substrate on which at least one circuit layer including a connection pad is formed on an insulating layer, may be the printed circuit board. Although FIG. 1 shows a case in which a specific inner layer circuit configuration is omitted for convenience of explanation, it may be sufficiently recognized by those skilled in the art that a typical circuit substrate having at least one circuit layer formed on the insulating layer is used as the substrate.

As the insulating layer used in the substrate 100, a resin insulating layer may be used. As a material of the resin insulating layer, a thermo-setting resin such as an epoxy resin, a thermo-plastic resin such as polyimide, or a resin having a reinforcement material such as a glass fiber or an inorganic filler impregnated in the thermo-setting resin and the thermo-plastic resin, for example, a prepreg may be used. In addition, a thermo-setting resin, a photo-curable resin, and the like may be used. However, the material of the resin insulating layer is not particularly limited thereto.

Here, the metal root layer 111 may be made of copper, nickel, chrome, or an alloy thereof, but is not particularly limited thereto.

In addition, the metal root layer 111 may serve as a seed layer, thereby integrally assisting in improving adhesion with the circuit layer 121.

The circuit layer 121 may be made of any conductive metal for a circuit without limit and be typically made of copper in the printed circuit board.

In addition, a surface treatment layer (not shown) may be further formed on an exposed circuit layer, if necessary. The surface treatment layer may be formed by electro gold plating, immersion gold plating, organic solderability preservative (OSP) or immersion tin plating, immersion silver plating, electroless nickel and immersion gold (ENIG), direct immersion gold (DIG) plating, hot air solder leveling (HASL), or the like, for example The method of forming the surface treatment layer is not particularly limited thereto as long as it is known in the art.

FIG. 2 is a cross-sectional view of a printed circuit board 2000 according to another exemplary embodiment of the present disclosure.

As shown in FIG. 2, the printed circuit board 2000 according to another exemplary embodiment of the present disclosure may include a substrate 100, a metal root layer 111 formed by injecting and depositing metal particles into and on the substrate 100, and a circuit layer 121 formed on the metal root layer 111.

The metal root layer 111 may be formed on a region of the substrate 100 bonded to the circuit layer 121 and may have a discontinuous chain structure.

Here, the metal root layer 111 may be made of copper, nickel, chrome, or an alloy thereof, but is not particularly limited thereto.

In addition, the metal root layer 111 may serve as a seed layer, thereby integrally assisting in improving adhesion with the circuit layer 121.

Method of Manufacturing Printed Circuit Board

FIGS. 3 to 9 are process flow charts of a method of manufacturing a printed circuit board according to an exemplary embodiment of the present disclosure.

As shown in FIG. 3, a substrate 100 is prepared.

The substrate 100, which is a circuit substrate on which at least one circuit layer including a connection pad is formed on an insulating layer, may be the printed circuit board. Although FIG. 3 shows a case in which a specific inner layer circuit configuration is omitted for convenience of explanation, it may be sufficiently recognized by those skilled in the art that a typical circuit substrate having at least one circuit layer formed on the insulating layer is used as the substrate.

As the insulating layer used in the substrate 100, a resin insulating layer may be used. As a material of the resin insulating layer, a thermo-setting resin such as an epoxy resin, a thermo-plastic resin such as polyimide, or a resin having a reinforcement material such as a glass fiber or an inorganic filler impregnated in the thermo-setting resin and the thermo-plastic resin, for example, a prepreg may be used. In addition, a thermo-setting resin, a photo-curable resin, and the like may be used. However, the material of the resin insulating layer is not particularly limited thereto.

As shown in FIG. 4, a process of removing impurities or foreign materials from the substrate 100 is performed.

As shown in FIG. 5, moisture component and residual gas component which are able to remain in the substrate 100 may be removed by an outgassing process.

As shown in FIG. 6, a process of injecting metal particles 110 into the substrate 100 may be performed.

Here, the metal particle 110 may be made of copper, nickel, chrome, or an alloy thereof, but is not particularly limited thereto.

In addition, the process of injecting the metal particles 110 may include any one of an ion beam sputtering method, a DC sputtering method, and a RF sputtering method. In this case, increasing a power value allows discharged atoms to be infiltrated into the substrate 100.

In addition, an implant process may be performed by making an energy value of the discharged atom large.

As shown in FIG. 7, a metal root layer 111 may be formed by performing a heat treatment on the metal particles 110 to recombine the metal particles 110.

In this case, the metal root layer 111 may be formed in a discontinuous chain shape, which may be an irregular shape.

In addition, the metal root layer 111 may serve as a seed layer.

As shown in FIG. 8, a metal plating layer 120 may be formed on the formed metal root layer 111.

As shown in FIG. 9, an etching resist (not shown) may be formed on the formed metal plating layer 120.

In addition, a circuit layer 121 may be formed by patterning the etching resist (not shown) to correspond to a portion in which a circuit is to be formed.

The circuit layer 121 may be made of any conductive metal for a circuit without limit and be typically made of copper in the printed circuit board.

In addition, a surface treatment layer (not shown) may be further formed on an exposed circuit layer, if necessary. The surface treatment layer may be formed by electro gold plating, immersion gold plating, organic solderability preservative (OSP) or immersion tin plating, immersion silver plating, electroless nickel and immersion gold (ENIG), direct immersion gold (DIG) plating, hot air solder leveling (HASL), or the like, for example The method of forming the surface treatment layer is not particularly limited thereto as long as it is known in the art.

FIGS. 10 to 12 are process flow charts of a method of manufacturing a printed circuit board according to another exemplary embodiment of the present disclosure.

The method of manufacturing the printed circuit board according to another exemplary embodiment of the present disclosure is similar to the method of manufacturing the printed circuit board according to an exemplary embodiment of the present disclosure except for one difference.

Therefore, in order to avoid an overlap of a description, another exemplary embodiment of the present disclosure will be described based on a difference in the manufacturing method as compared to an exemplary embodiment of the present disclosure.

As shown in FIG. 10, a mask 130 having an opening in a region corresponding to a portion in which a circuit is to be formed on the substrate 100 may be formed.

In addition, a process of injecting metal particles 110 into the substrate 100 may be performed.

Here, the metal particle 110 may be made of copper, nickel, chrome, or an alloy thereof, but is not particularly limited thereto.

In addition, the process of injecting the metal particles 110 may include any one of an ion beam sputtering method, a DC sputtering method, and a RF sputtering method. In this case, increasing a power value allows discharged atoms to be infiltrated into the substrate 100.

In addition, an implant process may be performed by making an energy value of the discharged atom large.

Further, the mask 130 may be removed.

As shown in FIG. 11, a metal root layer 111 may be formed by performing a heat treatment on the metal particles 110 to recombine the metal particles 110.

In this case, the metal root layer 111 may be formed in a discontinuous chain shape, which may be an irregular shape.

In addition, the metal root layer 111 may be formed on a partial region of the substrate 100.

In addition, the metal root layer 111 may serve as a seed layer.

In addition, a metal plating layer 120 may be formed on the formed metal root layer 111.

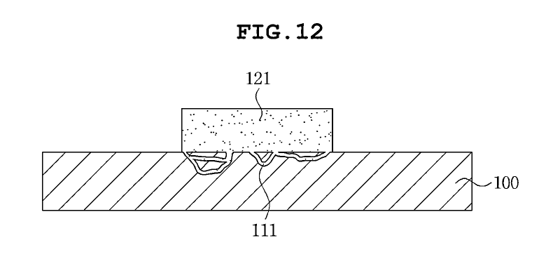

As shown in FIG. 12, an etching resist (not shown) may be formed on the formed metal plating layer 120.

In addition, a circuit layer 121 may be formed by patterning the etching resist (not shown) to correspond to a portion in which a circuit is to be formed.

As set forth above, according to the exemplary embodiments of the present disclosure, the printed circuit board and the method of manufacturing the same may form the metal thin film by injecting the metal particles into the substrate and then forming the coupling of the metal particles by the heat treatment. As a result, the adhesion between the metal thin film and the circuit layer may be secured and productivity may be improved.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A printed circuit board comprising:
a substrate;
a metal root layer formed by injecting and depositing metal particles into and on the substrate; and
a circuit layer formed on the metal root layer.

2. The printed circuit board of claim 1, wherein the metal root layer is formed on the entire surface of the substrate.

3. The printed circuit board of claim 1, wherein the metal root layer is formed on a region of the substrate bonded to the circuit layer.

4. The printed circuit board of claim 1, wherein the metal root layer has a discontinuous chain structure.

5. The printed circuit board of claim 1, wherein the metal root layer is made of cooper, nickel, chrome, or an alloy thereof.

6. A method of manufacturing a printed circuit board, the method comprising:
preparing a substrate;
injecting metal particles into the substrate;
depositing a metal root layer by applying heat to the metal particles; and
forming a circuit layer on the metal root layer.

7. The method of claim 6, wherein in the injecting of the metal particles, the metal particles are injected by sputtering.

8. The method of claim 6, further comprising, after the preparing of the substrate, removing foreign material from the substrate.

9. The method of claim 8, further comprising, after the removing of the foreign material from the substrate, removing moisture from the substrate.

10. The method of claim 6, further comprising,
before the injecting of the metal particles, forming a mask having an opening; and
after the injecting of the metal particles, removing the mask having the opening.

11. The method of claim 6, wherein the metal root layer is formed on a surface bonded to the circuit layer.

12. The method of claim 6, wherein the metal root layer is formed on the entire surface of the substrate.

13. The method of claim 6, wherein the metal root layer has a discontinuous chain structure.

14. The method of claim 6, wherein the metal root layer is made of cooper, nickel, chrome, or an alloy thereof.
